(19) United States
(12) Patent Application Publication
(10) Pub. No.: US 2006/0176073 A1
(43) Pub. Date: Aug. 10, 2006

(54) Clocked preconditioning of intermediate nodes

(75) Inventors: Ann H. Chen, Poughquag, NY (US); Paul A. Bunce, Poughkeepsie, NY (US); John D. Davis, Wallkill, NY (US); Donald W. Plass, Poughkeepsie, NY (US)

Correspondence Address: HESLIN ROTHENBERG FARLEY & MESITI P.C., 5 COLUMBIA CIRCLE, ALBANY, NY, 12203, US

(73) Assignee: International Business Machines Corporation, Armonk, NY (US)

(21) Appl. No.: 11/054,103

(22) Filed: Feb. 9, 2005

(51) Int. Cl. H03K 19/003

(52) U.S. Cl. 326/21

(57) ABSTRACT

A clocked bleeder device is used to precondition an intermediate node of an integrated circuit. The clocked bleeder device is activated by a clock signal. The clock signal activates the bleeder device at a time in which the integrated circuit is inactive. The clock signal controls the period of time in which the clocked bleeder device is active.

### TECHNICAL FIELD

This invention relates, in general, to integrated circuit design, and in particular, to preconditioning one or more intermediate nodes of one or more integrated circuits.

### BACKGROUND OF THE INVENTION

Integrated circuit design is complex, and thus, consideration is given to many factors when designing circuits. One of the factors considered includes the technology to be used. There are various technologies, each with its own strengths and weaknesses.

One available technology is the Complementary Metal Oxide Semiconductor (CMOS) technology, which is described in “Principles of CMOS VLSI Design: A Systems Perspective” by Weste and Eshraghian, 1993, which is hereby incorporated herein by reference in its entirety. With CMOS technology, there is a common problem known as the body effect when the field effect transistors (FETs) used to design a circuit are connected in series (referred to herein as a stack). For instance, in a stack of NFET transistors, the body effect occurs when the source of upper NFET transistors has a higher voltage than their body's, which is tied to the ground. The body effect causes performance degradation in the circuit due to higher threshold voltage.

To address this problem, a technology referred to as Silicon-On-Insulator (SOI) is used, which provides a floating body voltage. However, this technology has more complex design considerations. For instance, since the body voltage is easily coupled and displays history effect, analysis is more difficult and circuit delay can be varied from time to time.

Continually, there is a need to improve the various technologies and to design faster and more robust circuits. In an effort to meet this burden, a technique referred to as preconditioning has been used in one or more of the technologies to drive an intermediate node (e.g., a node in series with a plurality of transistors) to ground. This provides a more consistent loading for input signals of the transistors and provides a known initial state for the intermediate node.

Preconditioning has included the use of a long channel bleeder device to slowly bleed the intermediate node to ground. However, this bleeder device has not been capable of keeping up with advanced circuit design technologies.

Thus, a need exists for an improved bleeder device. For example, a need exists for a bleeder device that is usable in advanced technologies, such as lithographically aggressive technologies.

### SUMMARY OF THE INVENTION

The shortcomings of the prior art are overcome and additional advantages are provided through the provision of a preconditioning circuit. The circuit includes, for instance, a bleeder device to actively drive an intermediate node of an integrated circuit to a predefined state; and a clock signal to activate the bleeder device to drive the intermediate node to the predefined state.

In another aspect, a method of preconditioning intermediate nodes of integrated circuits is provided. The method includes, for instance, providing a bleeder device to actively drive an intermediate node of an integrated circuit to a predefined state; and activating via a clock signal the bleeder device to drive the intermediate node to the predefined state.

In yet a further aspect, an integrated circuit is provided. The integrated circuit includes, for instance, a plurality of transistors coupled in series with an intermediate node; the intermediate node being coupled to a bleeder device to actively drive the intermediate node to a predefined state, the bleeder device being activated by a clock signal.

Additional features and advantages are realized through the techniques of the present invention. Other embodiments and aspects of the invention are described in detail herein and are considered a part of the claimed invention.

### BRIEF DESCRIPTION OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one example of a circuit having an intermediate node that is preconditioned by a long channel bleeder device;

FIG. 2 depicts one example of a circuit having an intermediate node that is preconditioned by a clocked bleeder device, in accordance with an aspect of the present invention;

FIG. 3 depicts one example of a timing diagram for the circuit of FIG. 2, in accordance with an aspect of the present invention;

FIG. 4 depicts another example of a circuit having an intermediate node that is preconditioned by a clocked bleeder device, in accordance with an aspect of the present invention;

FIG. 5 depicts one example of a timing diagram for the circuit of FIG. 1; and

FIG. 6 depicts one example of a timing diagram for a circuit that does not employ intermediate node preconditioning.

### BEST MODE FOR CARRYING OUT THE INVENTION

In accordance with an aspect of the present invention, an improved bleeder device is provided that enhances preconditioning of intermediate nodes. As one example, the bleeder device is a clocked bleeder device that provides effective preconditioning of intermediate nodes, even in more aggressive technologies. Performance and speed of circuits are enhanced and noise margins are tolerated with use of the clocked bleeder device.

Preconditioning of an intermediate node (i.e., a node connected between transistors in series) enhances the performance of the logic circuit that includes that node. Preconditioning includes driving the intermediate node to a defined state, such as ground. Preconditioning provides various advantages including more consistent loading for the input signals arriving at the gate of each transistor in a stack (i.e., a plurality of transistors in series), since the devices are in source follower mode with similar body voltages. Also, there is less input capacitance for lower input(s) of the stack due to no Miller capacitance. Furthermore, there is less variability of the output signal due to less variation in the body voltage of devices in the stack. The same starting point or known state of the intermediate nodes can be counted on in every cycle. Thus, it gives less variability in circuit delay. Finally, it eliminates the need to seek steady state solution after tens of cycles of simulation or using a so-called body table for body voltage. Thus, preconditioning simplifies analysis.

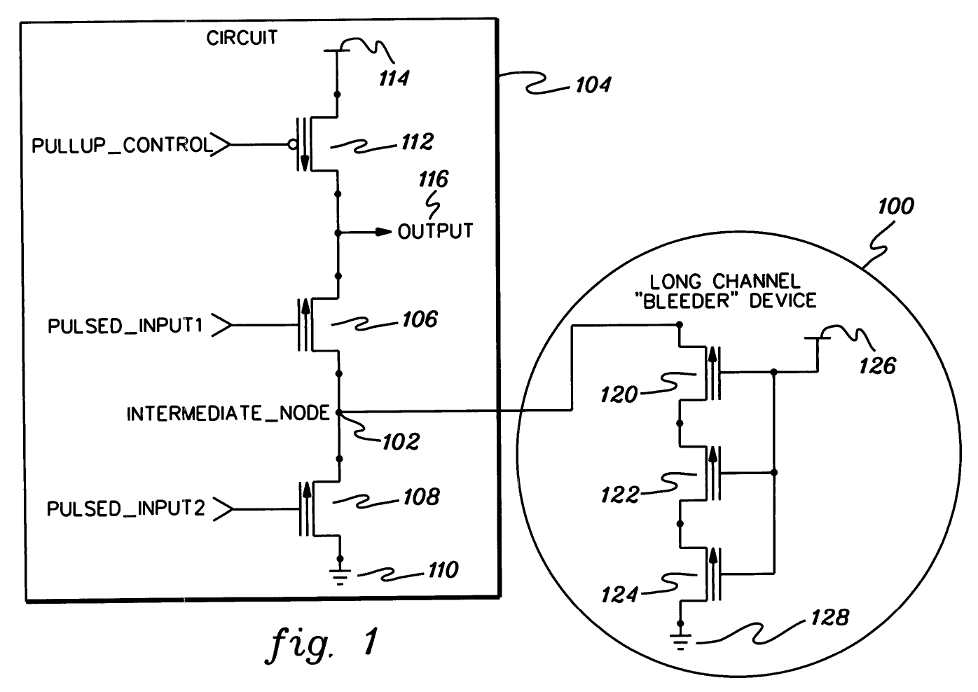

To perform preconditioning, a bleeder device coupled to the intermediate node is used. One example of a conventional bleeder device is depicted in FIG. 1. A long channel bleeder device 100 has previously been used to precondition an intermediate node 102 of a logic circuit 104. Intermediate node 102 is coupled to a plurality of transistors in series. For example, intermediate node 102 is coupled to a transistor 106 gated by pulsed_input1 and to a transistor 108 gated by pulsed_input2. Transistor 108 is tied to ground 110 and transistor 106 is in series with another transistor 112 which is tied to Vdd 114 and gated by a pullup_control. As is known, the pullup_control is used to precharge the circuit. The drains of transistors 106 and 112 are commonly connected and provide an output 116. In this example, transistor 112 is a PFET transistor and transistors 106 and 108 are NFET transistors.

Long channel bleeder device 100 includes a plurality of transistors 120, 122, and 124 in series. Each of the transistors is an NFET transistor and is gated to Vdd 126. The drain of transistor 120 is tied to intermediate node 102 and the source of transistor 124 is tied to ground 128. Since each transistor is gated to Vdd, the long channel bleeder device is always turned on. Thus, when the top transistor of the stack (e.g., controlled by pulsed_input1) becomes active, the current flows from the output to the intermediate node (i.e., a voltage divider). This enables the speed of the circuit to be increased. At this time, the output is not fully high. The circuit is designed so that it can tolerate the noise margin at the various manufacturing process corners and to enjoy the benefit of faster response due to switching from some high voltage level (less than Vdd) to ground. The optimal design point is carefully set at the tradeoff between the speed and noise margin.

Circuits are being designed to function in shorter cycle time for faster computers, and thus, faster response and recovery time are needed. However, the noise margin has become a more significant part of the power supply voltage as the scaling down of voltages in more lithographically aggressive technologies continues. It has become more difficult to balance the tradeoff between speed and noise margin. In particular, the current preconditioning circuits cannot be used in more aggressive technologies effectively with the same performance in terms of speed and noise margin.

Long channel devices have high threshold voltage implants to produce a weak transistor (i.e., a transistor with small current flow). The size of the devices of the bleeders is big enough to discharge or bleed the node to ground within the cycle time. In more advanced technologies, however, there is a need to increase the size of bleeder devices for faster recovery time; however, if the bleeder device is too big or strong, since the bleeder devices are tied to the power supply (meaning they are always turned on), it impacts the circuit's intended function to a certain extent. In a worse case scenario of a voltage divider between the intermediate node and the output, strong bleeder devices cause noise margin problems or even malfunctioning.

To overcome these disadvantages, as well as others, but still provide preconditioning, the long channel bleeder device is replaced by a clocked bleeder device, in accordance with an aspect of the present invention. The clocked bleeder device is a device (e.g., transistor) activated by a clock signal. The clock signal controls the period of time when the bleeder device is turned on.

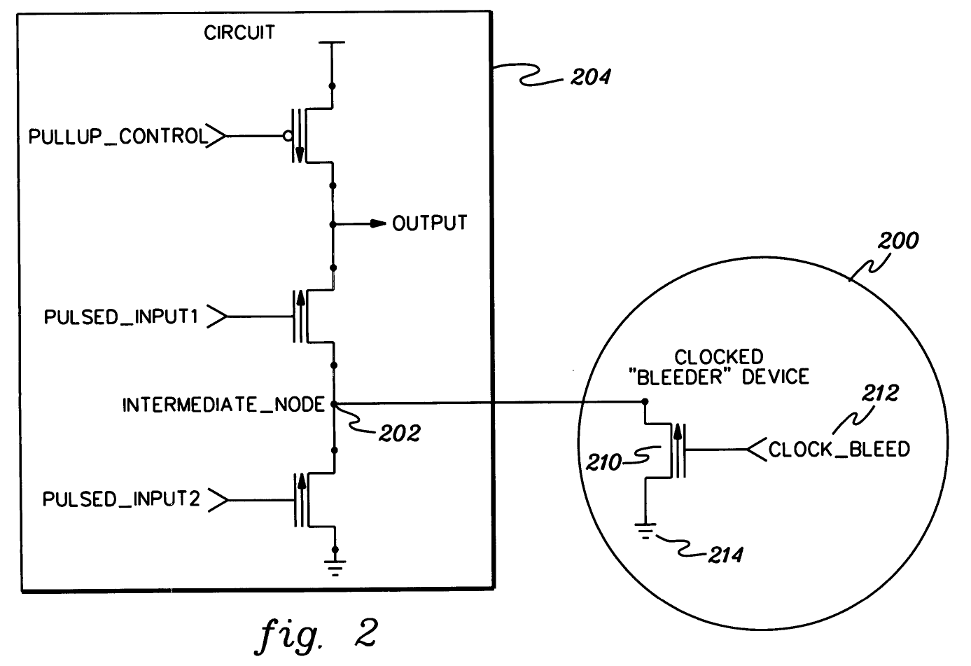

One embodiment of a clocked bleeder device is depicted in FIG. 2. As shown, a clocked bleeder device 200 is coupled to an intermediate node 202 of a circuit 204. The clocked bleeder device may be included as part of circuit 204 or in another circuit coupled thereto, as examples. In this particular example, various of the devices of circuit 204 are similar to those of circuit 104 described above, and thus, details regarding those devices are not repeated here. However, this circuit is only one example. Many circuits may benefit from one or more aspects of the present invention, including, but not limited to, employment of the clocked bleeder device.

Clocked bleeder device 200 includes, for instance, a transistor 210 gated by a clock bleed signal 212. Transistor 210 is, for instance, an NFET transistor, in which its source is tied to ground 214 and its drain is connected to intermediate node 202. In another example, transistor 210 may be a PFET transistor or another type of transistor or device.

Clock bleed signal 212 is a signal generated from a clock, such as a system clock. There are many ways in which the clock bleed signal can be generated. For example, if pulsed_input1 or pulsed_input2 is a clock signal, then the clock bleed signal can be generated from that clock signal. As one example, the clock bleed signal is the opposite phase as the input clock.

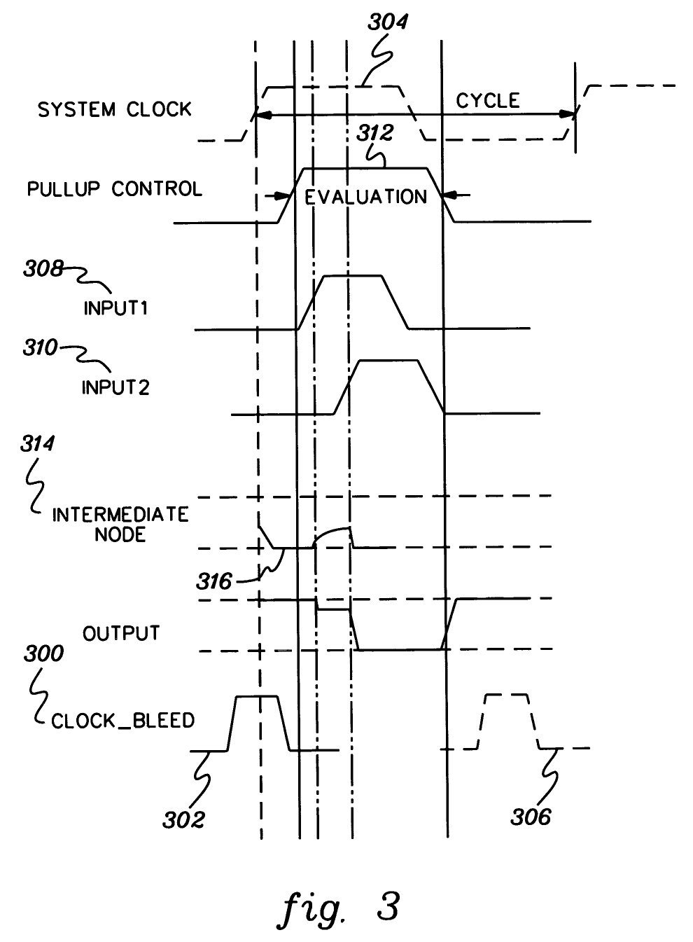

The clock bleed signal is activated, in one embodiment, at any time outside the window of time that circuit 204 is active. For instance, it is activated when pulsed_input1 and pulsed_input2 are inactive. It is inactive, for example, when pulsed_input1 and pulsed_input2 are active and/or during evaluation of the circuit. This is shown in the timing diagram of FIG. 3.

Referring to FIG. 3, a clock bleed signal 300 is, for instance, a short clock pulse at the beginning (302) of a clock cycle 304 or at the end (306) of the clock cycle. It is activated when input1 308 and input2 310 are low. Further, in this example, it is activated prior to or after an evaluation period 312 of the circuit. In response to activating the clock bleed signal, intermediate node 314 is driven to a predefined state, which in this example is ground, as indicated at 316. The drain of the intermediate node is very quick, in this example. The driving of the node to a predefined state enables the initial condition of the intermediate node to be known (e.g., set to zero).

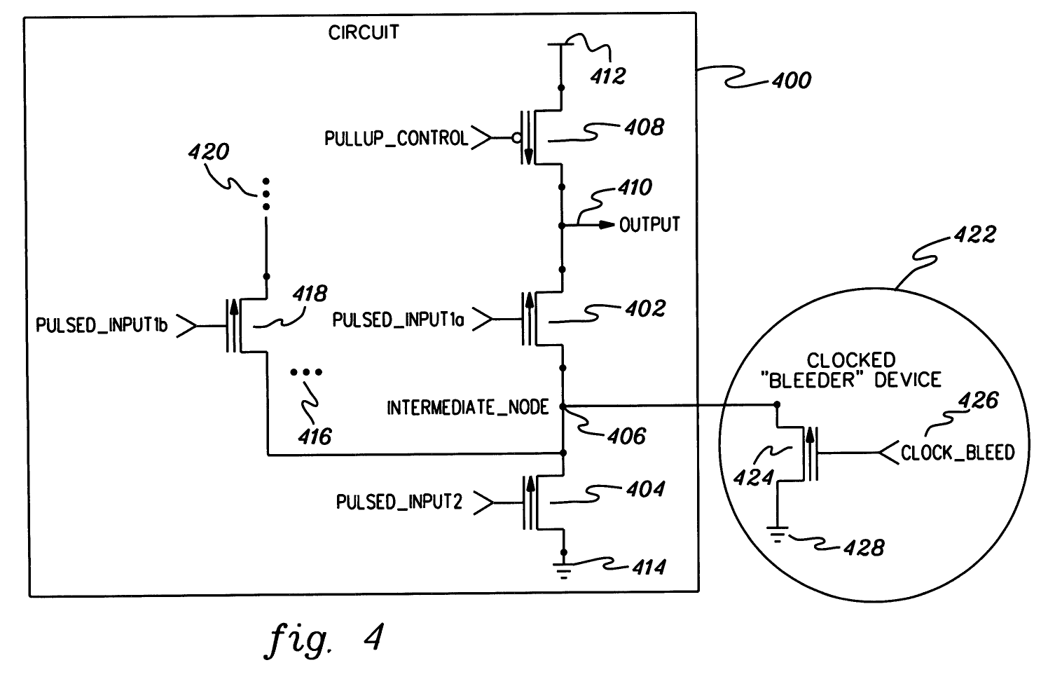

The clocked bleeder device is usable with many circuits, as indicated above. Another example of a circuit to use the clocked bleeder device is described with reference to FIG. 4. A circuit 400 includes a plurality of transistors 402 and 404 connected in series with an intermediate node 406. Transistors 402 and 404 are gated by pulsed_input1a and pulsed_input2, respectively. Transistor 402 is coupled to another transistor 408, which is gated by a pullup_control. The drains of transistors 402 and 408 are commonly connected and provide an output 410. Transistor 408 is tied to Vdd 412 and transistor 404 is tied to ground 414.

Portions of this circuit can be replicated as indicated by 416. For instance, at least one more transistor 418 gated by an input, pulsed_input1b, can be provided. Transistor 418 is coupled, for instance, to another transistor gated by a pullup_control as indicated by 420, or it can be connected to other transistors. Each of the replicated copies shares pulsed_input2, but has a different output (not shown). Such a circuit is usable as a decoder, for instance.

Intermediate node 406 is coupled to a clocked bleeder device 422. In this example, clocked bleeder device 422 is a transistor 424 gated by a clock bleed signal 426. Transistor 424 is, for instance, an NFET transistor, and its source is tied to ground 428 and its drain is tied to intermediate node 406. In other examples, however, transistor 424 may be a PFET transistor or another type of transistor or device.

The bleeder device, which is controlled by a pulsed bleeding clock, is turned on at the end of the previous cycle or at the beginning of the current cycle. The pulsed clock is off during the evaluation of the circuit, as one example. Thus, through the bleeder device, the initial condition of the intermediate node is set to, for instance, zero. In the case that the circuit is used as a building block to compose a decoder, as in the example of FIG. 4, among the many copies of the same circuit, the activated inputs propagate the logic through the output of the selected path. So, for the selected output, the inputs arrive, and through them, the output is discharged to ground. Without extra residual charges at the intermediate node from previous cycles, in addition to stronger current flow through transistor 402 due to more differential voltage across the device, the discharging action is faster than in the case of without preconditioning. As for the unselected output path, while a pulsed_input, such as input1a or input1b, is high and pulsed_input2 is low (i.e., transistor 404 is off), some of the charges at the output flow to the intermediate node (i.e., voltage divider). The bleeder resumes its responsibility of discharging the intermediate node next time when the bleeding clock is activated. Since the bleeder is not turned on at this time, there is no excessive current dissipation. A high voltage level can be compensated for (i.e., tune for noise margin tolerance) by variations of pull-up PFET.

In electrical simulation and analysis in a SOI technology, with this preconditioning technique of an aspect of the present invention, the delay through one circuit under test shows improvement in speed. A maximum benefit of this preconditioning bleeder can be seen, for instance, when all the pulsed inputs arrive about the same time. It is noted that based on our understanding and past experience, the benefit in terms of speed in bulk technology (e.g., CMOS technology) is greater than in SOI technology.

Described in detail above is one example of a clocked bleeder device used to precondition an intermediate node. The clocked bleeder device provides the advantages of preconditioning, while overcoming the design difficulty in tradeoff between noise margin and performance. The disadvantage of potential excessive power due to the constant bleeding path in previous devices is eliminated by designing the bleeding clock to avoid overlapping with the activation time of the circuit. The clocked bleeding device is active at one or more selected times when the circuit is inactive. The circuit is considered inactive, when it is outside the evaluation period and/or when one or more of the inputs are inactive, as examples. There may also be other definitions of inactive and they are included within the scope of one or more aspects of the present invention.

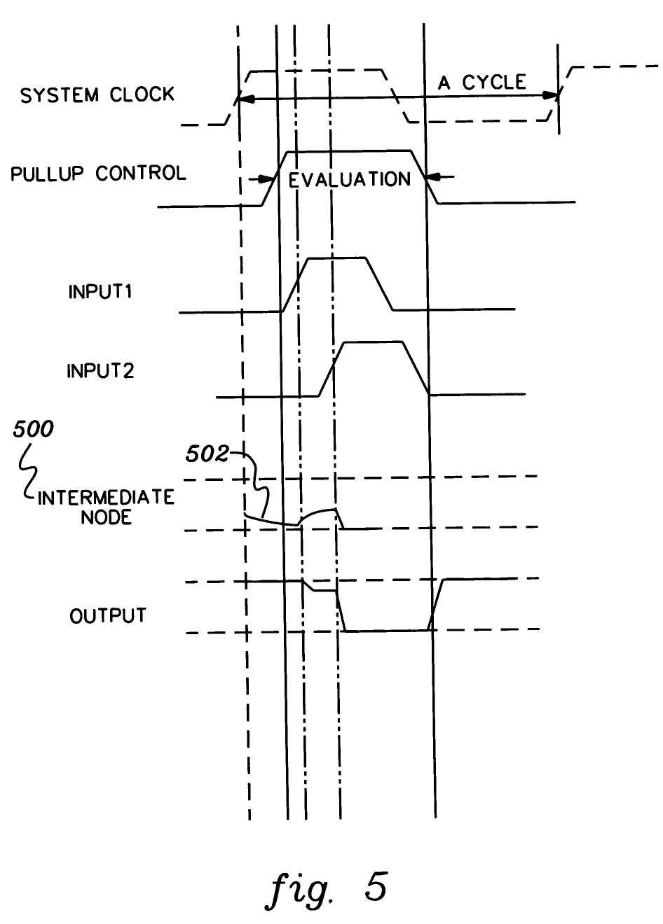

The clocked bleeder device of one or more aspects of the present invention actively drives the intermediate node to a predefined state (e.g., ground) faster than previously used bleeder devices. For instance, as shown in FIG. 5, with a long channel bleeder device, an intermediate node 500 is gradually drained 502 towards ground. It is not even at ground at its initial state. This type of bleed is always on. This is compared to the clocked bleeder device that quickly drains the intermediate node to ground, as shown at 316 in FIG. 3, and is only on at selected times.

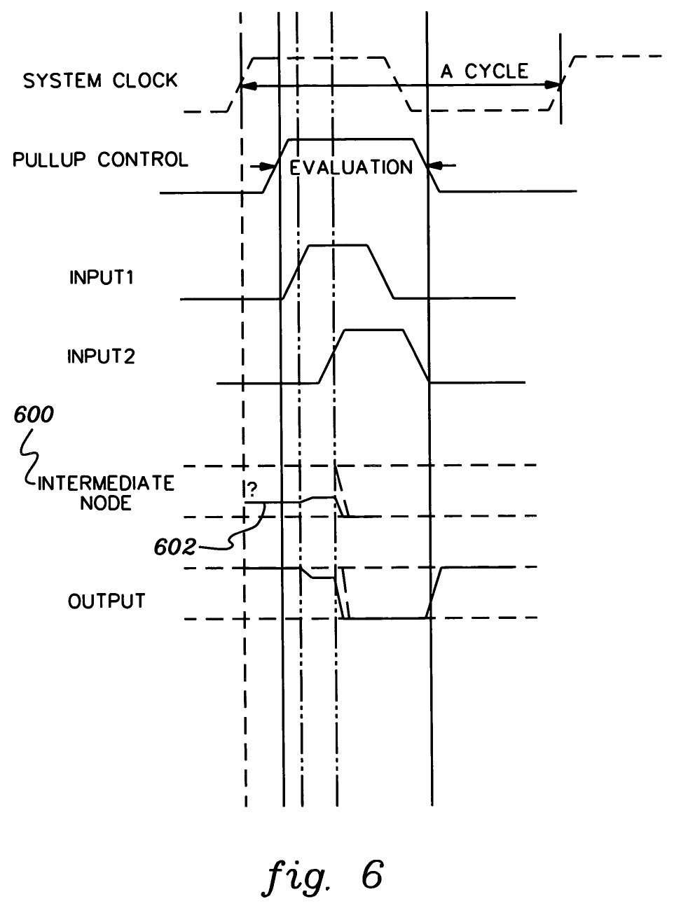

Preconditioning using a clocked device is further compared to no preconditioning at all, as shown in FIG. 6. An initial state of an intermediate node 600 is unknown 602, since the node is not actively driven to a known state.

Advantageously, the clocked bleeder device of one or more aspects of the present invention provides effective preconditioning in a host of technologies. It is capable of providing preconditioning such that the voltage divider has the same noise margin tolerance as in less advanced technologies for a boost in speed. That is, the clocked bleeder device possesses the advantages of other bleeder devices, while overcoming the design difficulty in tradeoff between noise margin and performance. The disadvantage of potential excessive power due to the constant bleeding path in other bleeders is eliminated by designing the bleeding clock to avoid overlapping with the activation time of the circuit.

The preconditioning capability of the present invention enhances the performance of the circuit employing the technique. As one example, the bleeder device of one aspect of the present invention actively drives an intermediate node to a predefined state that enables the overall circuit delay to be reduced to consistent charge sharing. The amount of reduction is dependent on a number of factors including, but not limited to, parasitic capacitance and device size. As one example, the delay is reduced to 3-10%. However, in other embodiments, the amount of reduction may vary.

Although various examples are described above, there may be many variations to these examples without departing from the spirit of the present invention. For example, there may be more than one clocked bleeder device for a circuit or multiple bleeding clock pulses within a single clock cycle, if desired. Further, the clocked bleeder device may be other than an NFET transistor, such as a PFET transistor or other type of transistor or device. Yet further, the clocked bleeder device may include a plurality of transistors or other devices. Moreover, the clocked bleeder device may actively drive the intermediate node to a state other than ground. As a further example, the intermediate node may be between transistors of a plurality of circuits. Yet further there may be more than one intermediate node in a circuit to benefit from preconditioning using one or more clocked bleeder devices. Another example is that the clock bleed signal can be generated from a clock other than the system clock. All these variations, including many others, are incorporated within the spirit of the present invention.

There may be many variations to the figures or circuits depicted and described herein without departing from the spirit of the invention. For instance, the number of transistors or the type of transistors may be different. All of these variations are considered a part of the claimed invention.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

What is claimed is:

1. A preconditioning circuit comprising:
a bleeder device to actively drive an intermediate node of an integrated circuit to a predefined state; and
a clock signal to activate the bleeder device to drive the intermediate node to the predefined state.

2. The circuit of claim 1, wherein the predefined state comprises ground.

3. The circuit of claim 1, wherein the intermediate node is coupled in series to a plurality of transistors of one or more integrated circuits.

4. The circuit of claim 3, wherein the clock signal is activated at a time in which one or more inputs to one or more transistors of the plurality of transistors are inactive.

5. The circuit of claim 1, wherein the bleeder device comprises a transistor.

6. The circuit of claim 5, wherein the transistor is gated by the clock signal.

7. The circuit of claim 1, wherein the clock signal is generated from a system clock of the integrated circuit.

8. The circuit of claim 1, wherein the bleeder device is activated at a time in which the integrated circuit is inactive.

9. The circuit of claim 1, wherein the clock signal controls a period of time in which the bleeder device is active.

10. A method of preconditioning intermediate nodes of integrated circuits, said method comprising:
providing a bleeder device to actively drive an intermediate node of an integrated circuit to a predefined state; and
activating via a clock signal the bleeder device to drive the intermediate node to the predefined state.

11. The method of claim 10, wherein the predefined state comprises ground.

12. The method of claim 10, wherein the intermediate node is coupled in series to a plurality of transistors of one or more integrated circuits.

13. The method of claim 12, wherein the activating comprises activating the clock signal at a time in which one or more inputs to one or more transistors of the plurality of transistors are inactive.

14. The method of claim 10, wherein the bleeder device comprises a transistor.

15. The method of claim 14, wherein the transistor is gated by the clock signal.

16. The method of claim 10, further comprising generating the clock signal from a system clock of the integrated circuit.

17. The method of claim 10, wherein the activating comprises activating the bleeder device at a time in which the integrated circuit is inactive.

18. The method of claim 10, wherein the clock signal controls a period of time in which the bleeder device is active.

19. An integrated circuit comprising:
a plurality of transistors coupled in series with an intermediate node; and
the intermediate node being coupled to a bleeder device to actively drive the intermediate node to a predefined state, the bleeder device being activated by a clock signal.

20. The integrated circuit of claim 19, wherein the clock signal controls a period of time in which the bleeder device is active.
